(19) United States
(12) Patent Application Publication
(10) Pub. No.: US 2004/0144488 A1
(43) Pub. Date: Jul. 29, 2004

(54) Semiconductor wafer processing apparatus

(75) Inventors: Takayuki Shoya, Kumamoto-shi (JP); Masaru Nagano, Hyogo (JP)

Correspondence Address: LEYDIG VOIT & MAYER, LTD, 700 THIRTEENTH ST. NW, SUITE 300, WASHINGTON, DC, 20005-3960, US

(73) Assignee: Renesas Technology Corp., Tokyo (JP)

(21) Appl. No.: 10/632,953

(22) Filed: Aug. 4, 2003

(30) Foreign Application Priority Data
Jan. 27, 2003 (JP) 2003-017269

(51) Int. Cl. H01L 21/306

(52) U.S. Cl. 156/345.24

(57) ABSTRACT

A photolithography apparatus includes: an air supply line supplying an air to a chamber processing a wafer; a temperature and humidity adjuster provided to the air supply line; a temperature and humidity monitoring sensor sensing temperature and humidity internal to the chamber; and a controller connected to the temperature and humidity monitoring sensor and the temperature and humidity adjuster to control the temperature and humidity adjuster to supply the chamber via the air supply line with an air having the same temperature and humidity as those of the air in the chamber detected by the temperature and humidity monitoring sensor.

### BACKGROUND OF THE INVENTION

1. Field of the Invention

The present invention relates generally to semiconductor wafer fabrication technology and particularly to semiconductor wafer fabrication technology in photolithography.

2. Description of the Background Art

Semiconductor wafers undergo a process including a deposition step, a photolithography step, an etching step and other various steps. Most of these steps require strictly controlled temperature.

Japanese Patent Laying-Open No. 5-251456 discloses an apparatus thermally processing semiconductor wafers, one at a time, which allows the wafers in a heating furnace to have a uniform temperature in their respective planes as well as among the wafers. This apparatus thermally processes semiconductor wafers introduced one by one into a heating furnace connected to a processing gas line provided with a gas temperature adjuster.

In this thermal processing apparatus the heating furnace can receive a processing gas having a temperature adjusted to stabilize the heating furnace's internal temperature so that semiconductor wafers can be processed with a more uniform temperature attained in each of their respective planes as well as between their substrates. Furthermore, it can reduce or eliminate a difference in temperature between the processing gas and a semiconductor substrate so that the semiconductor wafer can be processed without impaired uniformity in temperature in the plane and the processing gas supplied can also be free of variation in temperature to allow semiconductor wafers to be each processed without variation in temperature.

Japanese Patent Laying-Open No. 6-177056 discloses a gassing apparatus which provides heating to uniform a condition on a wafer for processing. This apparatus includes a processing chamber having an input/output port allowing an object to be processed to be input and output, a gas line connected to the processing chamber to supply a processing gas, a susceptor provided in the processing chamber to support the object to be processed, a plurality of divided heaters provided opposite the object supported by the susceptor to heat the susceptor's each different zone, and a controller controlling each divided heater individually to correspond to measurement data received from a device measuring a processing condition for the object processed in the processing chamber.

In this gassing apparatus the measured processing condition's profile data is used to obtain a profile in temperature for improvement to allow the processing condition's profile to be uniform across the object to be processed. To provide such a temperature profile each zone is heated by a respectively corresponding divided heater having a heating output controlled to provide a temperature profile allowing a uniform processing condition across the object to be processed. As a result, the object's internal processing condition can be stable and increased product yields can thus be provided.

As disclosed in Japanese Patent Laying-Open No. 5-251456, however, the thermal processing apparatus only adjust the temperature of a processing gas introduced into the heating furnace to stabilize the furnace's internal temperature. It does not consider any effects that other conditions of the processing gas have on semiconductor wafers' quality. As such, it cannot stabilize the wafers' quality based on the other conditions.

Furthermore, as disclosed in Japanese Patent Laying-Open No. 6-177056, the gassing apparatus measures as a condition of an object processed in the processing chamber a thickness of a processed film formed on a wafer and controls in temperature the plurality of divided heaters in a plasma chemical vapor deposition (plasma CVD) apparatus. Since the processed film's thickness is referred to to control the heaters' temperature, the gassing apparatus is not applicable to semiconductor processing apparatuses other than a CVD apparatus and the like performing a thin-film formation process.

### SUMMARY OF THE INVENTION

An object of the present invention is to provide a semiconductor wafer processing apparatus that allows an object or a semiconductor wafer to be processed to be uniform in quality.

Another object of the present invention is to provide a semiconductor wafer processing apparatus that allows an object or a semiconductor wafer to be photolithographically processed to be uniform in quality.

Still another object of the present invention is to provide a semiconductor wafer processing apparatus that readily allows an object or a semiconductor wafer to be processed to be uniform in quality.

Still another object of the present invention is to provide a semiconductor wafer processing apparatus that can avoid significantly increased cost for allowing an object or a semiconductor wafer to be processed to be uniform in quality.

The present invention in one aspect provides an apparatus processing a semiconductor wafer arranged in a chamber having an inlet supplying a fluid and an outlet exhausting the fluid. The apparatus includes: a detection portion detecting humidity in the chamber; and a control portion controlling a humidity adjustment device in accordance with the humidity detected by the detection portion.

In placing a wafer in the chamber and processing the wafer the chamber's internal humidity is controlled as based on a detected humidity and for example an air having the same humidity as that in the chamber is introduced into the chamber. Thus the air in the chamber has a uniform humidity and a resist, an acetal-based positive resist in particular, which has a reaction rate varying with humidity, applied on the wafer can be reacted at a constant rate. As a result, the chemically amplified resist can be reacted at a constant rate and the resist applied on the wafer can uniformly be processed.

The present invention in another aspect provides an apparatus processing a semiconductor wafer arranged in a chamber having an inlet supplying a fluid and an outlet exhausting the fluid. The apparatus includes: a detection portion detecting temperature and humidity in the chamber; and a control portion controlling a temperature and humidity adjustment device in accordance with the temperature and humidity detected by the detection portion.

In placing a wafer in the chamber and processing the wafer the chamber's internal temperature and humidity are controlled as based on a detected temperature and humidity and for example an air having the same temperature and humidity as those of the air in the chamber is introduced into the chamber. Thus the air in the chamber has uniform temperature and humidity and a resist, an acetal-based positive resist in particular, which has a reaction rate varying with humidity, applied on the wafer can be reacted at a constant rate. As a result, the chemically amplified resist can be reacted at a constant rate and the resist applied on the wafer can uniformly be processed.

The present invention in still another aspect provides an apparatus processing a semiconductor wafer arranged in a chamber, the apparatus being provided with a plurality of heaters controllable in temperature for each of a plurality of sections of a surface bearing the wafer. The apparatus includes: a measurement portion measuring a dimension of a pattern of a processed wafer in the apparatus, as correlated to the section; a detection portion detecting temperature in a vicinity of each heater; a calculation portion calculating a temperature instruction value for the heater of each section from the pattern's dimension measured by the measurement portion, as correlated to the section; and a control portion controlling the heater of each section to allow the detected temperature to attain the calculated temperature instruction value.

The apparatus includes a heater controlled to cancel a difference between a dimension of a pattern measured by the measurement portion and a target dimension of the pattern. As a result, any uneven dimension of a pattern attributed to uneven temperature can be canceled in processing a subsequent wafer by controlling the heater's temperature. The uneven dimension can thus be eliminated.

The present invention in still another aspect provides an apparatus processing a semiconductor wafer arranged in a chamber, there being provided an exposure device arranged at a position opposite the wafer, capable of controlling exposure in amount for each of a plurality of sections. The apparatus includes: a measurement portion measuring a dimension of a pattern of the wafer processed in the apparatus, as correlated to the section; a calculation portion calculating an exposure instruction value for each section from the dimension of the pattern measured by the measurement portion, as correlated to the section; and a control portion controlling the exposure in amount for each section so that the exposure device provides an amount of exposure corresponding to the calculated exposure instruction value.

The apparatus is provided with an exposure device providing an amount of exposure set to cancel a difference between a pattern's dimension measured by the measurement portion and a target dimension of the pattern. As a result, any uneven dimension of a pattern attributed to an uneven degree of exposure can be canceled in processing a subsequent wafer by controlling the current exposure. The uneven dimension can thus be eliminated.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram showing a photolithography apparatus of the present invention in a first embodiment;

FIG. 2 is a flow chart representing a control configuration of a program executed by a controller shown in FIG. 1;

FIG. 3 is a block diagram showing the photolithography apparatus of the present invention in a second embodiment;

FIG. 4 shows an arrangement of a heater and a temperature sensor;

FIG. 5 is a temperature table stored in a computer shown in FIG. 3;

FIG. 6 is a flow chart representing a control configuration of a program executed by a controller shown in FIG. 3;

FIGS. 7 and 8 illustrate an exemplary operation of the photolithography apparatus of the present invention in the second embodiment;

FIG. 9 is a block diagram of the photolithography apparatus of the present invention in a third embodiment;

FIG. 10 shows an arrangement of an exposure control section;

FIG. 11 is an exposure table stored in a computer shown in FIG. 9;

FIG. 12 is a flow chart representing a control configuration of a program executed by a controller shown in FIG. 9; and

FIG. 13 illustrates an exemplary operation of the photolithography apparatus of the present invention in the third embodiment.

### DESCRIPTION OF THE PREFERRED EMBODIMENTS

Hereinafter with reference to the drawings the present invention in embodiments will be described. Throughout the following description and the figures, like components are denoted by like reference characters. They are identical in name and function.

First Embodiment

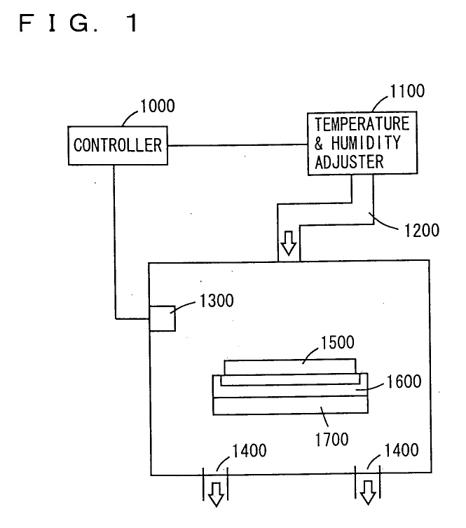

Hereinafter a photolithography apparatus of the present invention in a first embodiment will be described. As shown in FIG. 1, the photolithography apparatus includes a controller 1000 controlling the photolithography apparatus, a temperature and humidity adjuster 1100 adjusting the temperature and humidity of an air supplied to a chamber, an air supply line 1200 supplying air from temperature and humidity adjuster 1100 to the chamber, a temperature and humidity monitoring sensor 1300 provided internal to the chamber, and an exhaust line 1400 exhausting air from the chamber. Furthermore in the chamber a platform 1700 on which a wafer 1500 is placed and a hot plate 1600 arranged between platform 1700 and wafer 1500 are arranged.

In this photolithography process, wafer 1500 has a chemically amplified resist applied thereon and through a light blocking mask pattern the resist is exposed to light. The resist is partially, chemically reacted and remains on wafer 1500 at a portion corresponding the location of the mask.

When the chemically amplified resist applied on wafer 1500 is exposed to light, a photoacid generator generates acid, which is thermally processed to dissociate a blocking group linked with resin. The deblocked resin thus becomes soluble in a developer and a predetermined process can be performed. This chemically amplified resist includes a negative resist, an acetal-based positive resist, and an annealing resist. The acetal-based positive resist has a reaction rate depending not only on temperature but also humidity.

Controller 1000 receives a signal indicative of the temperature and humidity of an air internal to the chamber from temperature and humidity monitoring sensor 1300 provided in the chamber to monitor the temperature and humidity of the air internal to the chamber. Controller 1000 transmits the received temperature and humidity as a feedback control's target value to temperature and humidity adjuster 1100. Temperature and humidity adjuster 1100 adjusts the temperature and humidity of an air supplied to air supply line 1200 to attain the target value received from controller 1000. Note that humidity alone may be adjusted.

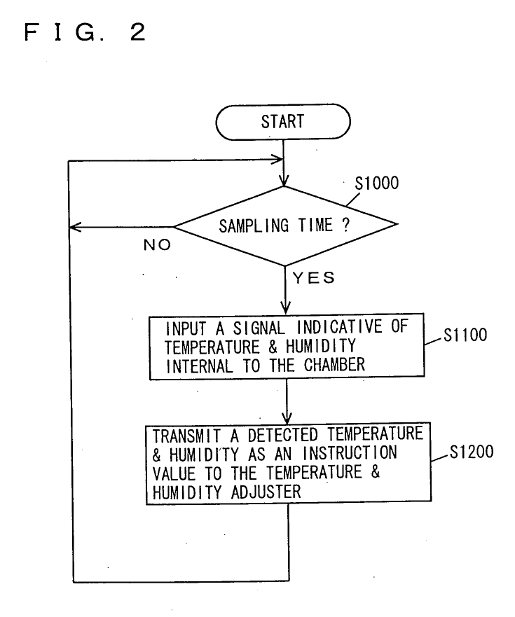

Reference will now be made to FIG. 2 to describe a control configuration of a program executed by controller 1000 shown in FIG. 1.

At step (S) 1000 controller 1000 determines whether a sampling time has been arrived at. If so (YES at S1000) the controller proceeds with S1100. Otherwise (NO at S1000) the control returns to S1000 and waits until a sampling time is arrived at.

At S1100 controller 1000 receives a signal indicating temperature and humidity detected by temperature and humidity monitoring sensor 1300 provided internal to the chamber.

At S1200 controller 1000 transmits the temperature and humidity received at S1100 as an instruction value (the feedback control's target value) to temperature and humidity adjuster 1100. The control then returns to S1000. Thus the S1000-S1200 steps are repeated for each sampling time (for example of 100 msec).

In accordance with the structure and flow chart as described above the photolithography apparatus of the present embodiment operates, as described hereinafter. Wafer 1500 is arranged in a chamber of the photolithography apparatus and a photolithography process starts. An air previously adjusted in temperature and humidity by temperature and humidity adjuster 1100 is introduced through air supply line 1200 into the chamber. The temperature and humidity of the air introduced into the chamber is detected by temperature and humidity monitoring sensor 1300 in the chamber and transmitted to controller 1000.

Controller 1000 responds to the received temperature and humidity by transmitting to temperature and humidity adjuster 1000 an instruction value (the feedback control's target value) corresponding to a control signal to achieve the same temperature and humidity as those of the air internal to the chamber. Temperature and humidity adjuster 1100 is driven by the received instruction value to effect feedback control targeted at the instruction value to control the temperature and humidity of an air to be introduced into the chamber so that the chamber can be supplied with an air controlled to have the same temperature and humidity as the air in the chamber.

Thus in the photolithography apparatus of the present embodiment when in a chamber a wafer is arranged and a photolithography process is performed the chamber is supplied with an air having the same temperature and humidity as that in the chamber. The chamber's internal air temperature and humidity can thus be uniformed. If in this condition the photolithography process is performed for the wafer with a resist, an acetal-based positive resist in particular, applied thereon, the uniform humidity allows the resist to be reacted at a constant rate. As a result, chemically amplified resist can be reacted at a constant rate, and the resist applied on the wafer can uniformly be solved.

Second Embodiment

Hereinafter the present photolithography apparatus in a second embodiment will be described. Note that the hardware configuration of the photolithography apparatus of the present embodiment described hereinafter that is the same as the apparatus of the first embodiment, will not be described hereinafter.

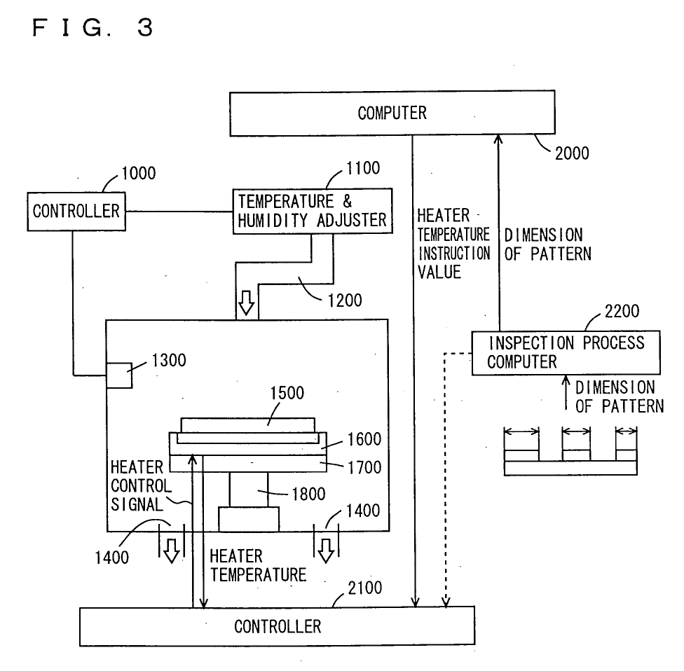

With reference to FIG. 3 the photolithography apparatus of the present embodiment provides a control block, as described hereinafter. As shown in the figure, the photolithography apparatus of the present embodiment has the hardware configuration of the photolithography apparatus of the first embodiment plus a rotative mechanism 180° rotating wafer platform 1700 horizontally. Furthermore, hot plate 1600 has a plurality of heaters and a temperature sensor sensing the temperature in the vicinity of the heaters. Furthermore in addition to controller 1000 connected to temperature and humidity adjuster 1100 and temperature and humidity monitoring sensor 1300 there is further included a controller 2100 connected to a computer 2000 and hot plate 1600. Computer 2000 is also connected to an inspection process computer 2200.

Inspection process computer 2200 measures a dimension of a pattern of wafer 1500 processed in the photolithography apparatus. In FIG. 3 a dimension of a pattern indicates a dimension of a portion corresponding to a resist applied on wafer 1500 that remains as it has not been solved.

A pattern having a large dimension indicates that the resist excessively remains, which in turn indicates that the chemically amplified resist's reaction is insufficient. This insufficient reaction can be attributed to hot plate 1600 having low temperature, and it can be resolved simply by increasing the plate's temperature, or providing increased exposure, as will be described later.

A pattern having a small dimension indicates that the resist is excessively solved, which in turn indicates that the chemically amplified resist's reaction has excessively proceeded. This excessive reaction can be attributed to hot plate 1600 having high temperature, and it can be resolved simply by reducing the plate's temperature, or providing reduced exposure, as will be described later.

Computer 2000 receives a pattern's dimension from inspection process computer 2200, calculates a heater temperature instruction value from the received dimension, and transmits the calculated heater temperature instruction value to controller 2100. Controller 2100 is driven by the received heater temperature instruction value to control feedback-control a heater of hot plate 1700. Controller 2100 receives a signal indicative of a heater temperature from a temperature sensor sensing the temperature of the plurality of heaters of hot plate 1600 and also transmits a heater control signal to hot plate 1600.

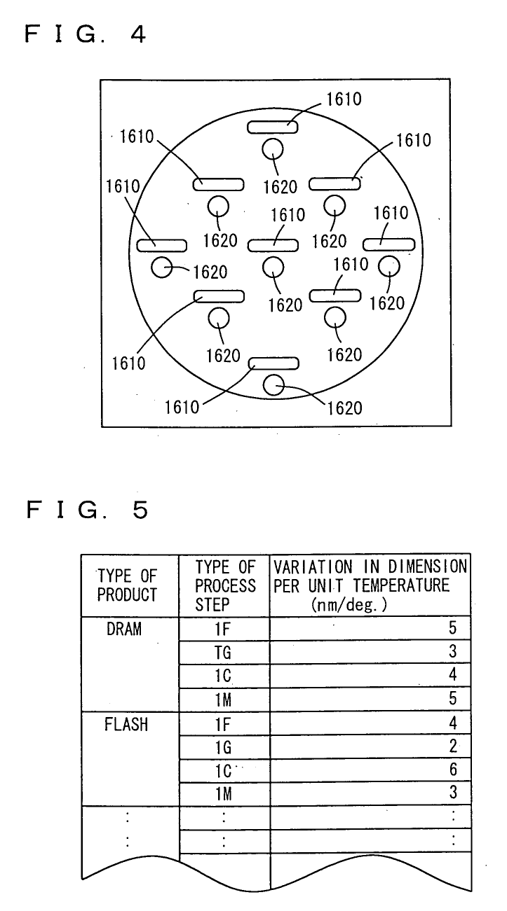

FIG. 4 shows an arrangement in hot plate 1600 of a heater 1610 and a temperature sensor 1620. The arrangement of heater 1610 and temperature sensor 1620 shown in FIG. 4 is set to correspond to an area in which inspection process computer 2200 measures a dimension of a pattern. More specifically, inspection process computer 2200 divides wafer 1500 into a plurality of areas (each for example of 20 mm by 20 mm for a wafer of 200 mm in diameter) and calculates an average value of dimensions of pattern in each area as a representative value of the dimensions in that area.

On the other hand, as shown in FIG. 4, heater 1610 and temperature sensor 1620 are arranged to correspond to the area. Note that it is not a requirement that a single measurement area in inspection process computer 2200 corresponds to a single area of hot plate 1600 for heater 1610 and temperature sensor 1620.

Furthermore, while inspection process computer 2200 is adapted to transmit a pattern's dimension to computer 2000, it is not limited thereto, and for example if the calculation of a heater temperature instruction value based on a pattern's dimension is set to be performed in inspection process computer 2200, inspection process computer 2200 may calculate a heater temperature instruction value and transmit the calculated value to control 2100.

Reference will now be made to FIG. 5 to describe a temperature table stored in computer 2000 at a fixed disc, memory or the like. As shown in FIG. 5, this temperature table stores variation in dimension per unit temperature for different types of semiconductor memory and different process steps. For example the table indicates that for a type “DRAM” and a step “1F” a heater temperature varying by one degree results in a pattern varying in dimension by 5 nm. Such a variation in dimension per unit temperature is stored for each type and each step.

If computer 2000 receives from inspection process computer 2200 a pattern's dimension smaller than a target dimension of the pattern, computer 2200 determines that the chemically amplified resist has been reacted excessively, and calculates a temperature instruction value to reduce the current temperature. If computer 2000 has received too large a dimension from inspection process computer 2200, computer 2000 determines that the chemically amplified resist is reacted insufficient, and calculates a temperature instruction value to increase the current temperature. In doing so, computer 2000 refers to the FIG. 5 temperature table to calculate a heater temperature instruction value.

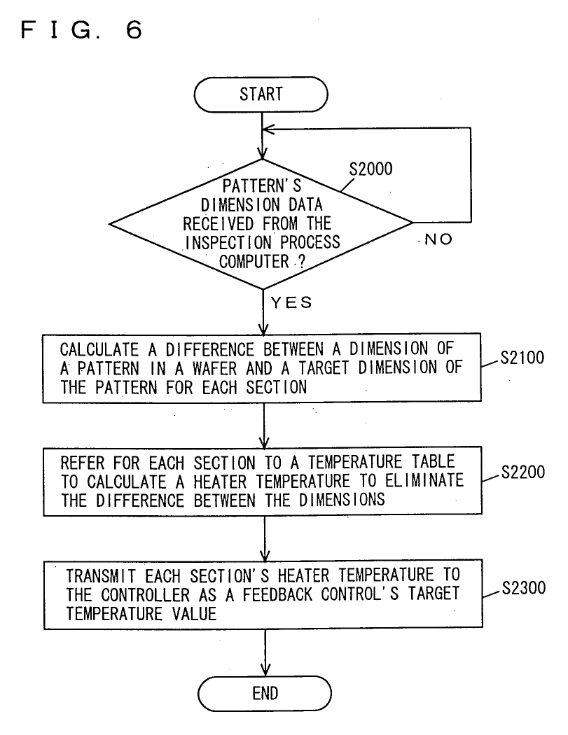

With reference to FIG. 6, computer 2000 executes a program having a control configuration, as described hereinafter.

At S2000 computer 2000 determines whether a pattern's dimension data has been received from inspection process computer 2200. If so (YES at S2000) the control proceeds with S2100. Otherwise (NO at S2000) the control returns to S2000 and waits until a pattern's dimension data is received from inspection process computer 2200.

At S2100 computer 2000 calculates a difference between a pattern's dimension in wafer 1500 and a target dimension of the pattern for each section. At S2200 computer 2000 refers for each section to the FIG. 5 temperature table to calculate a heater temperature to eliminate the difference between the dimensions.

At S2300 computer 2000 transmits each section's heater temperature to controller 2100 as a feedback control's target temperature value. Controller 2100 receives the heater temperature instruction value from computer 2000 and sets the value as a feedback signal's target value to control heater 1610. It should be noted that the feedback control is effected for each of the plurality of heaters 1610.

In accordance with the configuration and flow chart as described above the photolithography apparatus of the present embodiment operates, as described hereinafter.

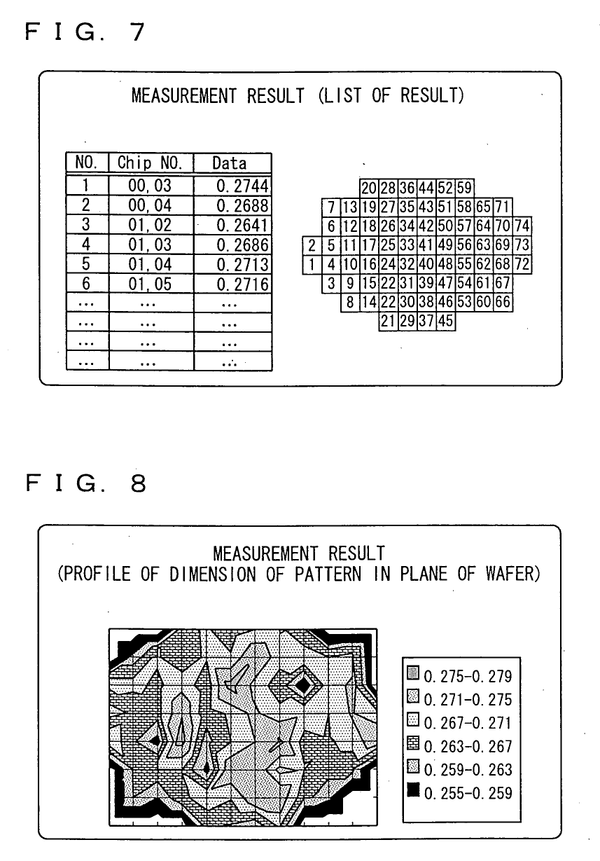

In this photolithography apparatus wafer 1500 undergoes a photolithography process and is then subjected to an inspection process. In the inspection process a pattern's dimension is measured. A measured pattern's dimension is input to inspection process computer 2000, which in turn transmits the received dimension to computer 2000 (YES at S2000). Computer 2000 having received the dimension calculates a difference between a dimension of a pattern in a wafer and a target dimension of the pattern for each section corresponding to an area in which the inspection process computer measures a dimension of a pattern (S2100). In doing so, FIG. 7 shows a result of measuring a dimension of a pattern. As shown in the figure, wafer 1500 is divided into 72 sections (or areas). For each area, a pattern's dimension data is measured.

Computer 2000 refers for each section to the FIG. 5 temperature table to calculate a heater temperature to eliminate the difference in dimension (S2200). If, as shown in FIG. 8, wafer 1500 provides an uneven dimension of a pattern, and the target dimension value of the pattern is 0.260 μm, the computer calculates a difference in value between a dimension of a pattern of each section show in FIG. 7 and the target dimension of the pattern, and if the dimension of the pattern of the section is larger than the target dimension of the pattern then a heater temperature increasing the current temperature is calculated and if it is smaller than the target dimension of the pattern then a heater temperature reducing the current temperature is calculated. In doing so, how many degrees the heater temperature should be changed is calculated, as corresponding to a variation in dimension to be introduced, with reference to the FIG. 5 temperature table. Thus a heater temperature is calculated to eliminate a difference between a measured pattern's dimension and a target dimension of the pattern.

From computer 2000 to controller 2100 a heater temperature instruction value is transmitted as a feedback control's target temperature value. Controller 2100 controls a value of a current of a power energizing heater 16100 so that a temperature detected by temperature sensor 1620 of hot plate 1600 attains the feedback control's target value.

In the present embodiment, as shown in FIG. 7, inspection process computer 2200 measures a pattern's dimension in 72 sections, whereas, as shown in FIG. 4, hot plate 1600 is provided with a pair of heater 1610 and temperature sensor 1620 arranged in each of nine sections. Accordingly, the 72 measurement sections are converted to the nine temperature control sections in controlling the temperature of hot plate 1600.

Furthermore, as shown in FIG. 3, the photolithography apparatus of the present embodiment has controller 1000, temperature and humidity adjuster 1100 and temperature and humidity monitoring sensor 1300 of the photolithography apparatus of the first embodiment. As such, to prevent the chamber from having an internal air uneven in temperature and humidity, an air adjusted to have the same temperature and humidity as detected by sensor 1300 is introduced into the chamber. Furthermore, wafer platform 1700 bearing wafer 1500 that is rotated by rotative mechanism 1800 horizontally can contribute to further uniform temperature and humidity.

Thus in the photolithography apparatus of the present embodiment a hot plate is provided with a plurality of heaters individually controlled to cancel a difference between a dimension of a pattern measured in an inspection process and a target dimension of the pattern. Any uneven dimension of a pattern attributed to uneven temperature of the hot plate can be canceled in processing a subsequent wafer by controlling the heater's temperature to eliminate the uneven dimension.

Third Embodiment

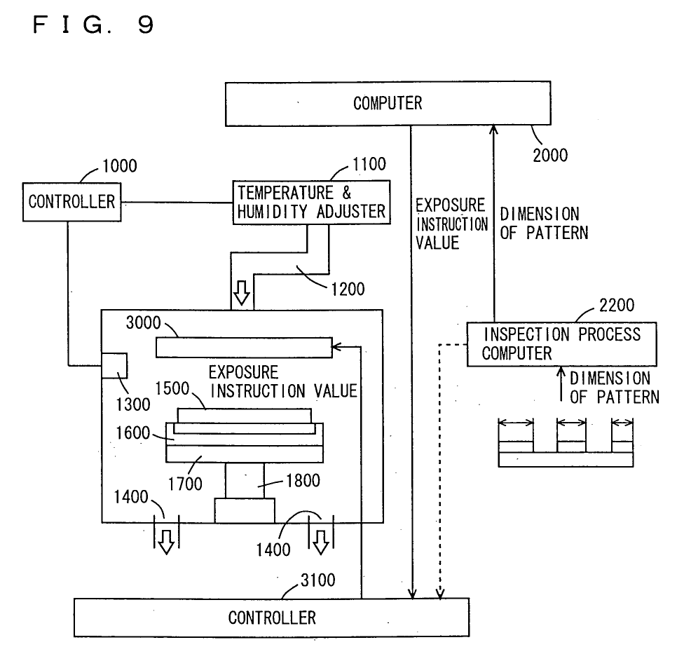

Hereinafter the present invention in third embodiment provides a photolithography apparatus, as described hereinafter. With reference to FIG. 9, the photolithography apparatus's control block diagram will be described. Note that the components shown in FIG. 9 that are identical to those shown in FIG. 3 are denoted identically. The components thus denoted are also identical in function.

As shown in FIG. 9, the photolithography apparatus of the present embodiment differs from that of the second embodiment in that the former includes an exposure device 3000 and a controller 3100 controlling exposure device 3000. Furthermore, computer 2000 uses a pattern's dimension received from inspection process computer 2200 and also refers to an exposure table, which will be described later, to calculate an exposure instruction value for transmission to controller 3100. Controller 3100 controls exposure device 3000 in accordance with the exposure instruction value received from computer 2000.

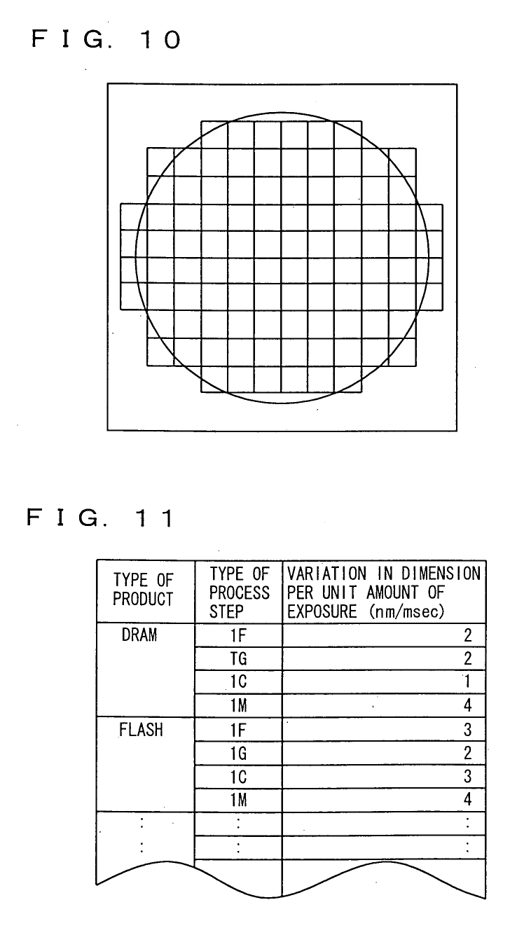

With reference to FIG. 10 a control section in exposure device 3000 is shown. The exposure device 3000 control section shown in FIG. 10 and the inspection process computer 2000 pattern measurement sections shown in FIG. 7 are not correlated one to one in number. Accordingly, as has been described in the second embodiment, a process is required to correlate a section of a dimension of a pattern measured by inspection process computer 2200 to a section of exposure device 3000. Note that a single pattern measurement area of FIG. 7 may be correlated to a single exposure control section of exposure device 3000 of FIG. 10.

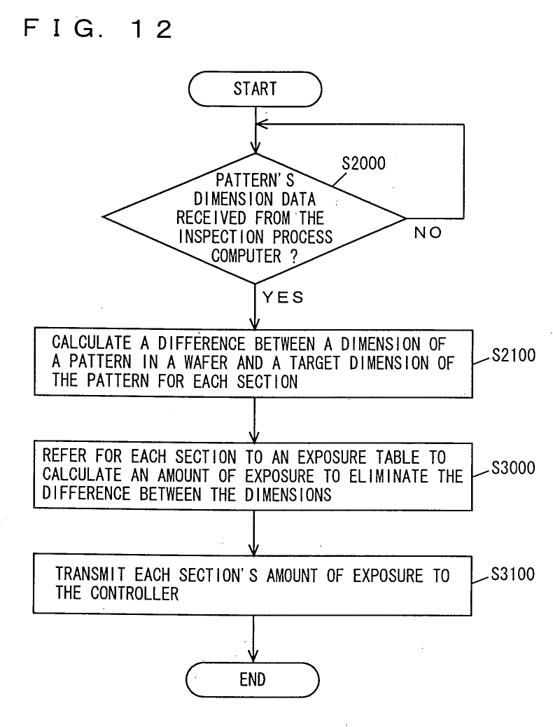

Reference will now be made to FIG. 11 to describe an exposure table stored in computer 2000 at a fixed disc or memory. As shown in the figure, the exposure table stores variation in dimension per unit amount of exposure for each product type and each process step. For example, as stored in the table, for a product type “FLASH” and a step “1F” an exposure time changed by 1 msec results in a pattern varying in dimension by 3 nm. For longer exposure times, the chemically amplified resist's reaction advances, and for shorter exposure times, the resist's reaction less proceeds. As such, a measured pattern's dimension larger than a target dimension of the pattern indicates an insufficient reaction and accordingly a longer exposure time is calculated to accelerate the reaction. A measured pattern's dimension smaller than the target dimension of the pattern indicates an excessive reaction and accordingly a shorter exposure time is calculated to decelerate the reaction. In doing so, the FIG. 11 exposure table is referred to in calculating a variation to be introduced in the current exposure time.

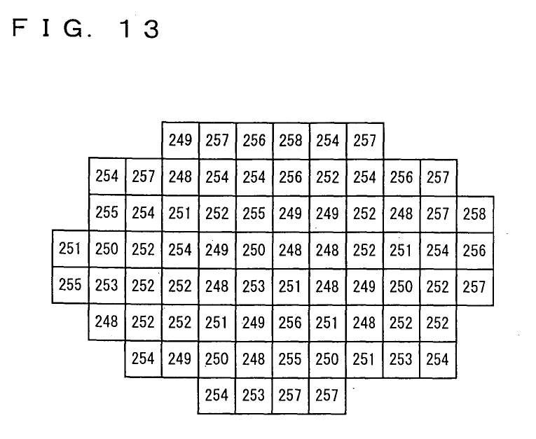

With reference to FIG. 12, computer 2000 executes a program having a control configuration, as described hereinafter.

The steps in the FIG. 12 flow chart that are identical to those shown in the FIG. 6 flow chart are identically denoted.

At S3000 computer 2000 refers for each section to the FIG. 11 exposure table to calculate an amount of exposure to eliminate a difference in dimension. In doing so, the exposure is calculated in the form of a time of exposure.

At S3100 computer 2000 transmits each section's amount of exposure to controller 3100. Controller 3100 having received each section's amount (or time) of exposure from computer 2000 as an exposure instruction value controls exposure device 3000 for each exposure control section to attain the exposure time.

In accordance with the configuration and flow chart as described above, the photolithography apparatus of the present embodiment operates, as described hereinafter. Wafer 1500 processed in the photolithography apparatus is moved to an inspection process in which a pattern's dimension is measured and input to inspection process computer 2200. Inspection process computer 2200 transmits the received dimension to computer 2000 (S2000). Computer 2000 calculates a difference between a dimension of a pattern of a wafer and a target dimension of the pattern for each section (S2100).

Computer 2000 refers for each section to the FIG. 11 exposure table to calculate an amount (or time) of exposure to eliminate the difference between the dimensions (S3000). Computer 2000 transmits the calculated amount (or time) of exposure to controller 3100. Controller 3100 controls exposure device 3100 in accordance with the exposure instruction value (the exposure time) received from computer 2000. In doing so, for example, as shown in FIG. 13, an exposure time is determined.

Thus in the photolithography apparatus of the present embodiment a dimension of a pattern of a wafer processed in the apparatus is measured and an exposure time is set to eliminate a difference between the measured dimension and a target dimension. The exposure time thus set is adapted in processing a subsequent wafer to resolve an uneven dimension of a pattern on the water.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. An apparatus processing a semiconductor wafer arranged in a chamber having an inlet introducing a fluid and an outlet exhausting said fluid, the apparatus comprising:
a detection portion detecting humidity in said chamber; and
a control portion controlling a humidity adjustment device in accordance with the humidity detected by said detection portion.

2. The apparatus according to claim 1, wherein said control portion calculates said detected humidity as an instruction value for said humidity adjustment device and in accordance with said instruction value controls said humidity adjustment device.

3. The apparatus according to claim 1, wherein:
said detection portion detects temperature and humidity in said chamber; and
said control portion calculates said detected temperature and humidity as an instruction value for said temperature and humidity adjustment device and in accordance with said instruction value controls said temperature and humidity adjustment device.

4. An apparatus processing a semiconductor wafer arranged in a chamber, said apparatus being provided with a plurality of heaters controllable in temperature for each of a plurality of sections of a surface bearing said wafer, said apparatus comprising:
a measurement portion measuring a dimension of a pattern of a processed wafer in said apparatus, as correlated to said section;
a detection portion detecting temperature in a vicinity of each said heater;
a calculation portion calculating a temperature instruction value for said heater of each said section from said dimension of said pattern correlated to said section measured by said measurement portion; and
a control portion controlling said heater of each said section to allow said detected temperature to attain said calculated temperature instruction value.

5. The apparatus according to claim 4, further comprising a storage portion previously storing a temperature table indicating a variation in dimension of a pattern for a unit temperature of said heater, wherein said calculation portion calculates a variation to allow said measured dimension of said pattern to attain a target value of said dimension of said pattern and calculates said temperature instruction value from said calculated variation and said stored temperature table.

6. An apparatus processing a semiconductor wafer arranged in a chamber, said apparatus being provided with a plurality of heaters controllable in temperature for each of a plurality of sections of a surface bearing said wafer, said apparatus comprising:
a receive portion connected to a measurement device to receive from said measurement device a dimension of a pattern of a processed wafer in said apparatus measured by said measurement device, as correlated to said section;
a calculation portion calculating a temperature instruction value for a heater of each section from the dimension of the pattern correlated to said section and received from said receive portion and;
a transmit portion transmitting said temperature instruction value to a temperature processing device controlling a temperature in a vicinity of said heater to attain said calculated temperature instruction value.

7. An apparatus processing a semiconductor wafer arranged in a chamber, there being provided an exposure device arranged at a position opposite said wafer, capable of controlling exposure in amount for each of a plurality of sections, the apparatus comprising:
a measurement portion measuring a dimension of a pattern of said wafer processed in said apparatus, as correlated to said section;
a calculation portion calculating an exposure instruction value for each section from the dimension of the pattern measured by said measurement portion, as correlated to said section; and
a control portion controlling said exposure in amount for each said section so that said exposure device provides an amount of exposure corresponding to said calculated exposure instruction value.

8. The apparatus according to claim 7, further comprising a storage portion previously storing an exposure table indicating a variation in dimension of a pattern for a unit exposure provided by said exposure device, wherein said calculation portion calculates a variation to allow said measured dimension of said pattern to attain a target value of said dimension of said pattern and calculates said exposure instruction value from said calculated variation and said stored exposure table.

9. An apparatus processing a semiconductor wafer arranged in a chamber, there being provided an exposure device arranged at a position opposite said wafer, capable of controlling exposure in amount for each of a plurality of sections, the apparatus comprising:
a receive portion connected to a measurement device to receive from said measurement device a dimension of a pattern of a processed wafer in said apparatus measured by said measurement device, as correlated to said section;
a calculation portion calculating an exposure instruction value for a heater of each section from the dimension of the pattern correlated to said section and received from said receive portion; and
a transmit portion transmitting said exposure instruction value to an exposure processing device controlling said exposure in amount to attain said calculated exposure instruction value.

10. An apparatus processing a semiconductor wafer arranged in a chamber having an inlet introducing a fluid and an outlet exhausting said fluid, said apparatus being provided with a plurality of heaters controllable in temperature for each of a plurality of sections of a surface bearing said wafer, said apparatus comprising:
a first detection portion detecting temperature and humidity in said chamber;
a first control portion controlling a temperature and humidity adjustment device in accordance with the temperature and humidity detected by said first detection portion;
a measurement portion measuring a dimension of a pattern of said wafer processed in said apparatus, as correlated to said section;
a second detection portion detecting temperature in a vicinity of each said heater;
a calculation portion calculating a temperature instruction value for said heater of each said section from the dimension of the pattern measured by said measurement portion, as correlated to said section; and
a second control portion controlling said heater of each said section to allow said detected temperature to attain said calculated temperature instruction value.

11. An apparatus processing a semiconductor wafer arranged in a chamber having an inlet introducing a fluid and an outlet exhausting said fluid, there being provided an exposure device arranged at a position opposite said wafer, capable of controlling exposure in amount for each of a plurality of sections, the apparatus comprising:
a detection portion detecting temperature and humidity in said chamber;
a first control portion controlling a temperature and humidity adjustment device in accordance with the temperature and humidity detected by said detection portion;
a measurement portion measuring a dimension of a pattern of said wafer processed in said apparatus, as correlated to said section;
a calculation portion calculating an exposure instruction value for each section from the dimension of the pattern measured by said measurement portion, as correlated to said section; and
a second control portion controlling said exposure in amount for each said section to allow exposure by said exposure device to attain said calculated exposure instruction value.

12. The apparatus according to claim 1, corresponding to a photolithography apparatus using a chemically amplified resist.

13. The apparatus according to claim 4, corresponding to a photolithography apparatus using a chemically amplified resist.

14. The apparatus according to claim 6, corresponding to a photolithography apparatus using a chemically amplified resist.

15. The apparatus according to claim 7, corresponding to a photolithography apparatus using a chemically amplified resist.

16. The apparatus according to claim 9, corresponding to a photolithography apparatus using a chemically amplified resist.

17. The apparatus according to claim 10, corresponding to a photolithography apparatus using a chemically amplified resist.

18. The apparatus according to claim 11, corresponding to a photolithography apparatus using a chemically amplified resist.
